(19) United States
(12) Patent Application Publication
(10) Pub. No.: US 2012/0244715 A1
(43) Pub. Date: Sep. 27, 2012

(54) HIGH-SELECTIVITY ETCHING SYSTEM AND METHOD

(75) Inventors: Kyle S. Lebouitz, Pittsburgh, PA (US); Andrew David Johnson, Doylestown, PA (US); Eugene Karwacki, JR., Orefield, PA (US); Suhas Narayan Ketkar, Allentown, PA (US); John Neumann, Pittsburgh, PA (US); David L. Springer, Pittsburgh, PA (US)

(73) Assignee: XACTIX, INC., Pittsburgh, PA (US)

(21) Appl. No.: 13/512,634

(22) PCT Filed: Dec. 2, 2010
(86) PCT No.: PCT/US2010/058713

§ 371 Date: May 30, 2012

Related U.S. Application Data
(60) Provisional application No. 61/265,927, filed on Dec. 2, 2009.
(60) Provisional application No. 61/382,207, filed on Sep. 13, 2010.

(51) Int. Cl. H01L 21/306; B05C 11/10; B44C 1/22

(52) U.S. Cl. 438/706; 216/41; 156/345.26; 257/E21.219

(57) ABSTRACT

In a method and system for vapor etching, a material to be etched and an etch resistant material are placed into an etching chamber. Thereafter, a pressure in the etching chamber is adjusted to a desired pressure and the substrate is exposed to an etching gas and a gas that comprises oxygen. The exposure substantially selectively etches the material to be etched while substantially avoiding the etching of the etch resistant material.

### BACKGROUND OF THE INVENTION

1. Field of the Invention

Vapor etching of semiconductor materials and/or substrates is accomplished using gases, such as xenon difluoride. Specifically, in xenon difluoride etching, xenon difluoride gas reacts with a solid material, such as silicon, germanium, silicon germanium, and molybdenum, such that the material is converted to a gas phase and removed. This removal of these materials is known as etching.

One key measure of the etching process is selectivity, which is the ratio of etching of the material to be etched versus those materials that are intended to remain, such as silicon dioxide and silicon nitride. Increases in selectivity ultimately lead to improved yield which is critical for high volume production and for the creation of specialized devices which require the high selectivity.

2. Description of the Prior Art

Improvements to the xenon difluoride etching process by adding non-etching gases have been described by Kirt Reed Williams, “Micromachined Hot-Filament Vacuum Devices,” Ph.D. Dissertation, UC Berkeley, May 1997, p. 396; U.S. Pat. No. 6,409,876; and U.S. Pat. No. 6,290,864. US Patent Application Publication No. US 2009/0071933 discusses the addition of oxygen to xenon difluoride to alter the etch process, primarily for trapping of MoOF4, but does not teach the benefit for etch selectivity.

A common prior art approach to xenon difluoride etching is through the pulsed method of etching In this mode, xenon difluoride is sublimated from a solid to a gas in an intermediate chamber, referred to as an expansion chamber, which can then be mixed with other gases. The gas(es) in the expansion chamber can then flow into an etching chamber to etch the sample, referred to as the etching step. The etching chamber is then emptied through a vacuum pump and this cycle, including the etching step, is referred to as an etching cycle. One or more etching cycles are repeated as necessary to achieve a desired amount of etching.

Alternatively, xenon difluoride etching in accordance with the prior art can be accomplished using a continuous method wherein a single reservoir is connected to a flow controller to provide a constant flow of xenon difluoride gas to a chamber where a sample to be etched resides. In addition, a means of mixing an additional, inert, gas with the etch gas between the outlet side of the flow controller and the inlet of the chamber is described.

### SUMMARY OF THE INVENTION

Vapor etching of semiconductor materials and/or substrates is accomplished using gases, such as xenon difluoride. Specifically, in xenon difluoride etching, xenon difluoride gas reacts with solid materials such as, without limitation, silicon, germanium, tungsten, titanium, zirconium, hafnium, vanadium, tantalum, niobium, boron, phosphorous, arsenic, silicon germanium, molybdenum, and mixtures thereof, such that the materials are converted to a gas phase and removed. The removal of these materials is known as etching.

One key measure of an etching process is selectivity, which is the ratio of etching of the material to be etched versus those materials that are intended to remain, such as, without limitation, silicon dioxide, silicon nitride, silicon carbon nitride, silicon oxynitride, nickel, aluminum, photoresist, phosphosilicate glass, boron phosphosilicate glass, polyimides, gold, copper, platinum, chromium, aluminum oxide, silicon carbide, titanium, tantalum, tantalum-nitride, titanium-nitride, tungsten, titanium-tungsten, and mixtures thereof. Increases in selectivity ultimately lead to improved yield which is critical for high volume production and for creation of specialized devices which require the high selectivity.

It is to be appreciated that, based on the application, a material to be etched in one application can be a material that is intended to remain in another application. Non-limiting examples of such materials include, without limitation, titanium, tantalum, and tungsten.

The selectivity benefit of adding oxygen is shown herein for at least three scenarios of etching: 1) by using as part of a pulsed etching cycle where oxygen and xenon difluoride are mixed in an expansion chamber before each etching cycle; 2) by using pulses of pure xenon difluoride in the etching cycle but also flushing with oxygen between each etching cycle; and 3) by adding a flow of oxygen to the xenon difluoride etching gas flow in a continuous process. Other etching scenarios which use oxygen as part of the etching process are also contemplated. The selectivity improvement for etching silicon versus silicon nitride and silicon dioxide is demonstrated but similar selectivity improvement is expected for other materials, including, without limitation: silicon carbide and silicon carbon nitride. Selectivity improvement is also anticipated for materials, such as titanium, titanium tungsten, titanium nitride, and tungsten.

Mixtures of gases which include oxygen or are used in place of the oxygen are also envisioned. Also, other oxidizing gases, such as, without limitation: nitrous oxide, which may require additional heat or other energy to be effective; or ozone, which could be created using an ozone generator; oxygen atoms, which could be created using an oxygen plasma; nitrogen dioxide, which may require additional heat or other energy to be effective; and carbon dioxide, which may require additional heat or other energy to be effective could be used in place of, or in addition to, oxygen.

In addition, other vapor phased etching gases, such as, without limitation, elemental fluorine, bromine trifluoride, krypton difluoride, chlorine trifluoride, and combinations of these gases, for example, could be used in addition to or in place of xenon difluoride. The use of a gas comprising oxygen in the manner described herein is expected to improve the selectivity of any of the etching gases described herein. Furthermore, this concept of adding oxygen is believed to also improve the selectivity of xenon difluoride or other vapor phased etching gases generated in situ; for example, using NF3/Xenon plasmas, F2/Xenon plasmas, CF4/Xenon plasmas, or SF6/Xenon plasmas.

More specifically, the invention is a vapor etching method comprising: (a) placing a substrate comprising a material to be etched and an etch resistant material into an etching chamber; (b) following step (a), adjusting a pressure in the etching chamber to a desired pressure; and (c) following step (b), exposing the substrate in the etching chamber to an etching gas and to an amount of a gas that comprises oxygen that is selected to obtain a desired selectively ratio of a change in the material to be etched caused by said exposure over a change in the etch resistant material caused by said exposure.

The change in the material to be etched caused by said exposure can be either (1) a change in a mass of the material to be etched caused by said exposure or (2) a change in a dimension of the material to be etched caused by said exposure. The change in the etch resistant material caused by said exposure can be a change in a dimension of the etch resistant material caused by said exposure.

The selectively ratio is desirably no less than 60. More specifically, the selectively ratio is desirably between 60 and 125000.

Step (c) can include exposing the materials to either a continuous flow of the etching gas diluted with the gas that comprises oxygen or to plural pulses of etching gas diluted with the gas that comprises oxygen.

The dilution of the etching gas with the gas that comprises oxygen can occur either prior to or concurrent with said exposure.

Step (c) can include sequentially exposing the materials to (1) the etching gas and (2) to the gas that comprises oxygen. Alternatively, step (c) can include sequentially exposing the materials to (1) the etching gas absent the gas that comprises oxygen and (2) to the gas that comprises oxygen absent the etching gas. Step (c) can also include sequentially exposing the substrate to the etching gas and the gas that comprises oxygen for a number of cycles.

The etching gas can include one or more of the following gases: fluoride, xenon difluoride gas, bromine trifluoride gas, krypton difluoride gas, and chlorine trifluoride gas. The gas that comprises oxygen can be one or more of the following gases: O₂, ozone, nitrous oxide, nitric oxide, carbon dioxide, and carbon monoxide. The material to be etched can be comprised of one or more of the following: silicon, germanium, tungsten, titanium, zirconium, hafnium, vanadium, tantalum, niobium, boron, phosphorous, arsenic, and molybdenum. The etch resistant material can be comprised of one or more of the following: silicon dioxide, silicon nitride, silicon carbon nitride, silicon oxynitride, nickel, aluminum, photoresist, phosphosilicate glass, boron phosphosilicate glass, polyimides, gold, copper, platinum, chromium, aluminum oxide, silicon carbide, titanium, tantalum, tantalum-nitride, titanium-nitride, tungsten, and titanium-tungsten.

The invention is also a vapor etching system comprising: an etching chamber; a vacuum pump; a plurality of valves; and a controller operative for controlling the opening and the closing of the valves to: cause the vacuum pump to reduce pressure in the etching chamber to below atmospheric pressure when an etch resistant material and a material to be etched are positioned in the etching chamber; cause an etching gas to be supplied to the pressure reduced etching chamber; and cause an amount of gas comprising oxygen to be supplied to the pressure reduced etching chamber, either concurrent with the supply of etching gas or separate from the supply of etching gas, that produces a desired ratio of etching of the material to be etched versus etching of the etch resistant material.

The system can further include at least one mass flow controller for controlling a rate that the etching gas, the gas comprising oxygen, or both are supplied to the pressure reduced etching chamber.

The system can further include an expansion chamber, wherein the controller is operative for controlling the plurality of valves to charge the expansion chamber with the etching gas and for causing the etching gas to be supplied to the pressure reduced etching chamber from the expansion chamber.

Prior to causing the etching gas to be supplied to the pressure reduced etching chamber from the expansion chamber, the controller controls the plurality of valves to charge the expansion chamber with the etching gas diluted with the gas comprising oxygen.

The controller is also or alternatively operative for causing the gas comprising oxygen to be supplied to the pressure reduced etching chamber concurrent with the supply of etching gas to the pressure reduced etching chamber from the expansion chamber.

The controller is also or alternatively operative for: causing plural pulses of the etching gas to be supplied to the pressure reduced etching chamber; and causing the gas comprising oxygen to be supplied to the pressure reduced etching chamber between at least one pair of temporally adjacent pulses of the etching gas.

Each pulse of etching gas can be supplied to the pressure reduced etching chamber absent the gas comprising oxygen being supplied to the pressure reduced etching chamber. Each pulse of gas comprising oxygen can be supplied to the pressure reduced etching chamber absent the etching gas being supplied to the pressure reduced etching chamber.

Lastly, the invention is a vapor etching method comprising: (a) providing a substrate comprised of a material to be etched and at least one etch resistant material; (b) exposing said substrate to an etching gas in the presence of a pressure below atmospheric pressure; and (c) exposing said substrate to an amount of gas comprising oxygen, in the presence of a pressure below atmospheric pressure, that produces a desired ratio of etching of the material to be etched versus etching of the etch resistant material, wherein the substrate is exposed to the gas comprising oxygen either concurrent with the exposure of said substrate to the etching gas in step (b) or separately from the exposure of said substrate to the etching gas in step (b).

The method can further include repeating steps (b) and (c) until the etch resistant material has been etched to a least a predetermined extent.

Exposing the substrate to the gas comprising oxygen concurrent with the exposure of said substrate to the etching gas can include either: diluting the etching gas with the gas comprising oxygen in a chamber prior to said exposure or combining separate flows of the gas comprising oxygen and the etching gas just prior to said exposure.

Also or alternatively, exposing the substrate to the gas comprising oxygen separately from the exposure of said substrate to the etching gas can include: exposing said substrate to a number of separate instances of the etching gas, and between at least two instances of exposing said substrate to the etching gas, exposing said substrate to an instance of the gas comprising oxygen.

The material to be etched can be comprised of one or more of the following: silicon, germanium, tungsten, titanium, zirconium, hafnium, vanadium, tantalum, niobium, boron, phosphorous, arsenic, and molybdenum. The etch resistant material can be comprised of one or more of the following: silicon dioxide, silicon nitride, silicon carbon nitride, silicon oxynitride, nickel, aluminum, photoresist, phosphosilicate glass, boron phosphosilicate glass, polyimides, gold, copper, platinum, chromium, aluminum oxide, silicon carbide, titanium, tantalum, tantalum-nitride, titanium-nitride, tungsten, and titanium-tungsten.

### BRIEF DESCRIPTION OF THE DRAWINGS

FIG. 1 is a schematic diagram of an etching system that can be utilized to implement the present invention;

FIG. 2 is a plan view of a selectivity test setup A;

FIG. 3 is a cross-sectional view taken along lines in FIG. 2;

FIG. 4 is the selectivity test setup A shown in FIG. 3 inside of the vacuum chamber;

FIG. 5 is a cross-section of a wafer used in a selectivity test setup B;

FIG. 6 is a cross-section of a sample used in selectivity test setup B;

FIG. 7 is a plan view of a sample on the aluminum carrier in selectivity test setup B;

FIG. 8(A) is a cross-section view of an etched sample sitting on an aluminum carrier in selectivity test setup B;

FIG. 8(B) is an isolated perspective view of one opening in the silicon dioxide layer of the etched sample shown in FIG. 8(A);

FIG. 9 is a cross-section view of a wafer used in selectivity test setup C;

FIGS. 10(A)-10(C) are plan views of three masks used in the selectivity test setup C with the wafer shown in FIG. 9;

FIG. 11 is a cross-section of a portion (quarter) of the wafer shown in FIG. 9;

FIG. 12 is a cross-section of a portion (quarter) of the wafer shown in FIG. 9 on an aluminum carrier;

FIG. 13 is a plan view of a portion (quarter) of the wafer shown in FIG. 9 on an aluminum carrier;

FIGS. 14(A)-14(C) are graphs showing the effect of increasing xenon difluoride pressures on etch rate, for different oxygen partial pressures; and

FIGS. 15(A)-15(C) are graphs showing the effect of increasing oxygen partial pressures on selectivity, for different xenon difluoride pressures.

### DETAILED DESCRIPTION OF THE INVENTION

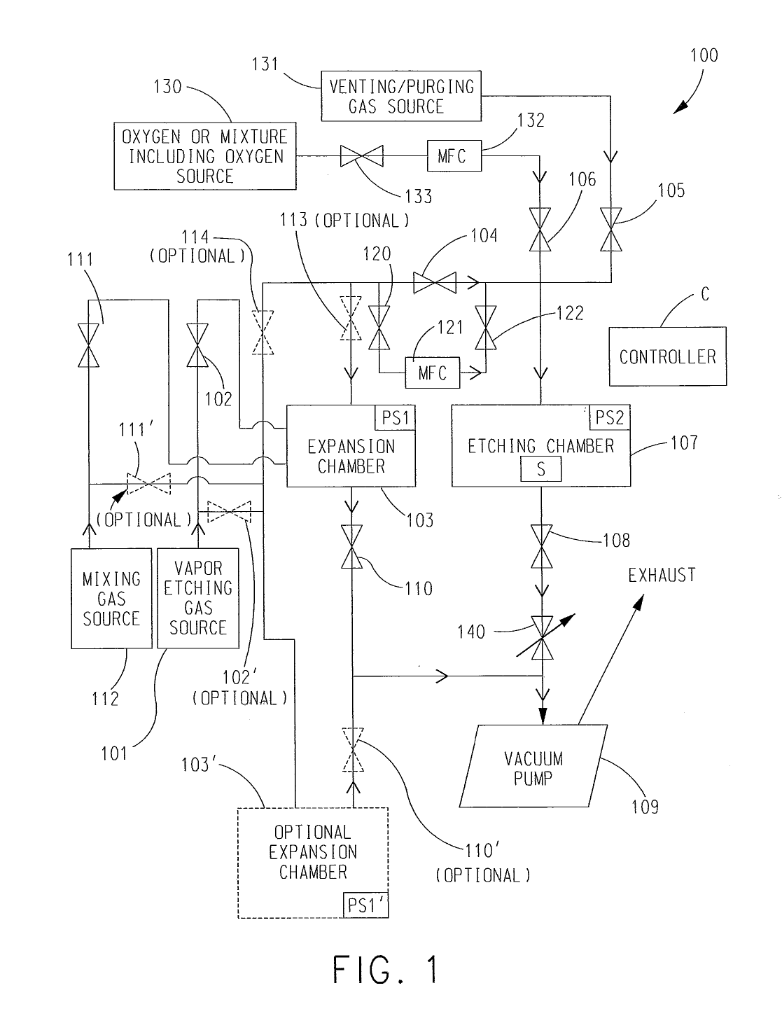

With reference to FIG. 1, a vapor etching system 100 includes a vapor etching gas source 101, which is usually a cylinder of gas, such as xenon difluoride, connected to a valve 102. Valve 102 is connected to an expansion chamber 103 which is used as an intermediate chamber to regulate the quantity of etching gas in each cycle. Expansion chamber 103 can optionally be evacuated by a vacuum pump 109 via a valve 110. Expansion chamber 103 includes a pressure sensor PS1, which is typically a capacitance diaphragm gauge. Expansion chamber 103 is connected to a mixing gas source 112 via a valve 111 which allows one or more mixing gases, such as oxygen and/or nitrogen, to be mixed with the xenon difluoride in expansion chamber 103. A needle valve (not shown) can also be in series with valve 111 and additional valves (not shown) to provide additional control of the flow of mixing gases. Expansion chamber 103 is connected to an etching chamber 107 via a flow path that includes either a valve 104 or a mass flow controller (MFC) 121 and valves 120 and 122.

Etching chamber 107 can be vented or filled with an inert purging gas via valve 105, to raise the pressure in etching chamber 107 to atmosphere for opening. The pressure in etching chamber 107 is monitored using a pressure sensor PS2, which is desirably a capacitance diaphragm gauge. A needle valve (not shown) or other flow restrictor can also be in series with valve 105 to provide additional control of the purging gas. The pressure in etching chamber 107 is desirably controlled using an automatic pressure controller 140 which adjusts the fluid conductance between etching chamber 107 and vacuum pump 109. Vacuum pump 109 is desirably a dry vacuum pump. In addition, the connection between etching chamber 107 and vacuum pump 109 can be fully isolated via a vacuum valve 108.

A computer or other similar controller C, such as a programmable logic controller, running under the control of a non-transitory computer program stored in a memory of said computer, desirably controls the operation of the values described herein to implement the present invention. Manual operation is possible, but is not typical.

Other modifications to the system 100 disclosed in FIG. 1 are anticipated, such as those described in U.S. Pat. No. 6,887,337 (incorporated herein by reference) including, without limitation, variable volume expansion chambers, one or more optional expansion chambers 103′ and optional valves 110′, 113 and 113′, and multiple gas sources.

In addition, other vapor phased etching gases, such as bromine trifluoride, krypton difluoride, chlorine trifluoride, and combinations of these gases, for example, could be used in addition to or in place of xenon difluoride.

A typical etching sequence is to load a sample S into etching chamber 107. Etching chamber 107 is then evacuated via vacuum pump 109 and automatic pressure controller 140 by opening and then closing vacuum valve 108. Typically, etching chamber 107 is pumped down to about 0.3 Torr, but this is not to be construed as limiting the invention. Etching chamber 107 may be further purged of atmosphere by closing vacuum valve 108, opening valve 105, and introducing a venting/purging gas, such as nitrogen, argon, or other inert or inert gas mixture gas, from a venting/purging gas source 131 into etching chamber 107 to approximately 400 Torr (anywhere from 1 Torr to 600 Torr would be useful, though), whereupon valve 105 is closed. Etching chamber 107 is then evacuated of the venting/purging gas by vacuum pump 109 via automatic pressure controller 140 by opening and then closing vacuum valve 108 upon when reaching a suitable evacuation pressure.

The sequential pumping down of etching chamber 107 to a pressure ≦1 Torr, e.g., 0.3 Torr, and then purging etching chamber 107 with venting/purging gas is repeated typically three or more times to minimize moisture and undesired atmospheric gases in etching chamber 107. The purpose of these pumps and purges is to remove from etching chamber 107 moisture which can react with xenon difluoride and other etching gases to form hydrofluoric acid which can attack many non-silicon materials.

At a suitable time, etching chamber 107 is pumped down to a suitable low pressure, e.g., 0.3 Torr, and etching is performed on sample S in etching chamber 107. After etching is complete, etching chamber 107 is purged of etching gas by vacuum pump 109 by opening valve 108. Once etching chamber 107 is purged of etching gas, valve 108 is closed.

Etching chamber 107 can be further purged of any residual etching gases by opening valve 105 and introducing venting/purging gas, typically nitrogen, into etching chamber 107 to approximately 400 Torr (anywhere from 1 Torr to 600 Torr would be useful, though). Thereafter, vacuum pump 109 removes venting/purging gas from etching chamber 107 and reduces the pressure in etching chamber 107 to a low pressure, typically less than 0.3 Torr, by opening and then closing valve 108.

The sequential purging of etching chamber 107 with venting/purging gas and then removing the venting/purging gas from etching chamber 107 and pumping etching chamber 107 to a low pressure is repeated typically three or more times to minimize residual etch related gases in etching chamber 107. At a suitable time, etching chamber 107 is vented to atmosphere to remove etched sample S. Etching chamber 107 can include a load-lock such that sample S can be transferred into etching chamber 107 under vacuum whereupon etching chamber 107 does not need to be vented to atmosphere for each change of sample S.

Pulsed Etching Sequence:

A pulsed based etching sequence will now be described. Expansion chamber 103 is evacuated to a desired low pressure, typically around 0.3 Torr, via vacuum pump 109 by opening valve 110. Once the pressure in expansion chamber 103 has reached the desired low pressure, valve 110 is closed and expansion chamber 103 is filled to the desired pressure of etching gas from etching gas source 101 by opening and then closing valve 102. Mixing gas from mixing gas source 112 can optionally be included in expansion chamber 103 with the etching gas by opening and then closing valve 111. The mixing gas from mixing gas source 112 can be, without limitation, oxygen or an oxygen gas mixture.

Once expansion chamber 103 has been charged with the gas(es) to be used for etching sample S (the etching gas(es)), expansion chamber 103 is connected to etching chamber 107 (which includes sample S loaded therein) by opening valve 104, whereupon the etching gas(es) flow into etching chamber 107 and etch sample S for a time referred to as the etch time. After this etch time, etching chamber 107 and expansion chamber 103 are evacuated by vacuum pump 109 by opening valve 108 while valve 104 is maintained opened. After expansion chamber 103 has been pumped down to a sufficiently low pressure, such as 0.8 Torr, valve 104 is closed and valve 110 is opened, whereupon expansion chamber 103 is further pumped down by vacuum pump 109 to a desired lower pressure, typically 0.3 Torr or less. Once expansion chamber 103 has been further pumped down to the desired lower pressure, valve 110 is closed. Etching chamber 107 can also be pumped down to a desired low pressure, typically less than 0.3 Torr, by open valve 108. Once etching chamber 107 has been pumped down its desired low pressure, valve 108 is closed.

A flush of gas between etch cycles can also be incorporated by introducing venting/purging gas from venting/purging gas source 131 through valve 105 or by introducing an oxygen or oxygen mixture from a source 130 thereof through a valve 133, a mass flow controller (MFC) 132, and a valve 106. The need for valve 133 and MFC 132 for this purpose is optional since the pressure in etching chamber 107 can be monitored by pressure sensor PS2 and the oxygen or oxygen mixture flow from source 130 can be stopped using valve 106 when the target pressure in etching chamber 107 is reached.

The venting/purging gas from venting/purging gas source 131 or the oxygen or oxygen mixture from source 130 desirably remains in etching chamber 107 for a time typically on the order of one to tens of seconds. After this time, referred to as the flush time, etching chamber 108 is evacuated by opening valve 108. Once etching chamber 108 has been evacuated to a desired low pressure, typically less than 0.3 Torr, valve 108 is closed.

Alternatively to the flush of gas between etch cycles described above, a constant flow and controlled pressure of gas can be introduced between etch cycles. Specifically, MFC 132 and valves 133 and 106 can be utilized to introduce a controlled flow of oxygen or oxygen mixture from source 130 into etching chamber 107, which can be pressure controlled using pressure controller 140. Optionally, the flushing of etching chamber 107 with venting/purging gas from venting/purging gas source 131 or oxygen or oxygen mixture from source 130 can be done before the etch sequence begins or after the etch sequence ends.

The above process of filling expansion chamber 103 with etching gas(es); introducing the etching gas(es) into pumped down etching chamber 107 from expansion chamber 103; evacuating the etching gas(es) from etching chamber 107 and expansion chamber 103; and flushing of etching chamber 107 with venting/purging gas or oxygen or an oxygen mixture can continue until the etching of sample S is deemed complete.

Continuous Etching Sequence

Also or alternatively to the pulsed etching sequence described above, sample S can be etched by a continuous etching sequence. In a continuous etching sequence, expansion chamber 103 is evacuated to a desired low pressure, typically to around 0.3 Torr, by vacuum pump 109 via open valve 110. Once expansion chamber 103 has been evacuated to the desired low pressure, valve 110 is closed and expansion chamber 103 is filled to the desired pressure of etching gas from etching gas source 101 by opening and then closing valve 102.

With valve 104 closed and with valve 108 open, whereupon vacuum pump 109 is coupled to etching chamber 107 via pressure controller 140, valves 120 and 122 are opened, whereupon etching gas flows from expansion chamber 103 into etching chamber 107 via MFC 121. Optionally, oxygen or an oxygen mixture from source 130 is added to etching chamber 107 along with the etching gas by opening valves 106 and 133, whereupon the optional oxygen or oxygen mixture flows through MFC 132 into etching chamber 107.

The etching gas and optional oxygen or oxygen mixture flows into etching chamber 107 for the etch time. During this etch time, the pressure inside etching chamber 107 is controlled by pressure controller 140. After the etch time, valves 122 and 106 are closed, and etching chamber 107 is evacuated by vacuum pump 109 to a desired low pressure, typically less than 0.3 Torr, whereupon valve 108 is closed. Expansion chamber 103 and MFC 121 are pumped down to a desired low pressure, typically 0.3 Torr, by opening valve 110 and then closing valves 110 and 120 after this desired low pressure is reached.

A pulsed-continuous etching sequence could also be implemented, wherein a continuous flow of etching gas is provided to etching chamber 107, by the addition of another expansion chamber 103′ and valves 110′, 113, 102′ and 114 (all shown in phantom in FIG. 1) to system 100. In this pulsed-continuous etching sequence, valves 110, 110′, 113, 102, 102′, 114, 120, 122, and 108 are selectively controlled to individually fill each expansion chamber 103 and 103′ with etching gas from etching gas source 101 at a time when said expansion chamber is not being utilized to supply etching gas to etching chamber 107, and to discharge the fill or charge of etching gas in each expansion chamber 103 and 103′ one at a time. For example, starting from a state where expansion chamber 103 is filled with etching gas and expansion chamber 103′ is not filled with etching gas, valves 110, 110′, 102, and 114 are closed, and valves 113, 120, 121, and 108 are opened to introduce the charge of etching gas in expansion chamber 103 into etching chamber 109. While etching chamber 109 is being fed with etching gas from expansion chamber 103, valve 102′ is opened to fill optional expansion chamber 103′ with etching gas from etching gas source 112 (desirably before the charge of etching gas in expansion chamber 103 is depleted), whereupon valve 102′ is closed. At a suitable time before the charge of etching gas in expansion chamber 103 becomes depleted to the point that it can no longer support a continuous flow of etching gas into etching chamber 109, valves 114 and 113 are controlled to couple optional expansion chamber 103′ to etching chamber 109 and to isolate expansion chamber 103 from etching chamber 109 in a manner that maintains a substantially continuous flow of etching gas into etching chamber 109. Thereafter, expansion chamber 103 is filled with etching gas (desirably before the charge of etching gas in optional expansion chamber 103′ is depleted) from etching gas source 112 by opening and then closing valve 102. At a suitable time before the charge of etching gas in optional expansion chamber 103′ becomes depleted to the point that it can no longer support a continuous flow of etching gas into etching chamber 109, valves 114 and 113 are controlled to couple expansion chamber 103 to etching chamber 109 and to isolate optional expansion chamber 103′ from etching chamber 109 in a manner that maintains a substantially continuous flow of etching gas into etching chamber 109. The foregoing process of sequentially supplying etching gas to etching chamber 109 from one expansion chamber 103, 103′ while filling the other expansion chamber 103, 103′ with etching gas continues until sample S has been etched to a desired extent.

If it is desired for the purpose of pulsed-continuous etching to also introduce mixing gas(es), such as oxygen, to the etching gas in each expansion chamber 103, 103′, an optional valve 111′ can be added to system 100. Valves 111 and 111′ can then be controlled to selectively combine mixing gas(es) into each expansion chamber 103, 103′ along with the charge of etching gas to be fed to etching chamber 107 from said expansion chamber, prior to the introduction of the combination of etching gas and mixing gas(es) from said expansion chamber into etching chamber 107. Note valves 110 and 110′ would typically be used to evacuate expansion chambers 103 and 103′ before filling/refilling.

Additional modifications to the continuous etch sequence could include the introduction of the oxygen or oxygen mixture from source 130 before the etch begins and/or after the etch ends. In addition, the oxygen or oxygen mixture from source 130 could be temporarily flowed without etching gas during various intervals during the etch sequence. Alternatively, the etching gas could be temporarily flowed without the oxygen or oxygen mixture during various intervals during the etch sequence.

### EXAMPLES

### Descriptions of Selectivity Test Setups

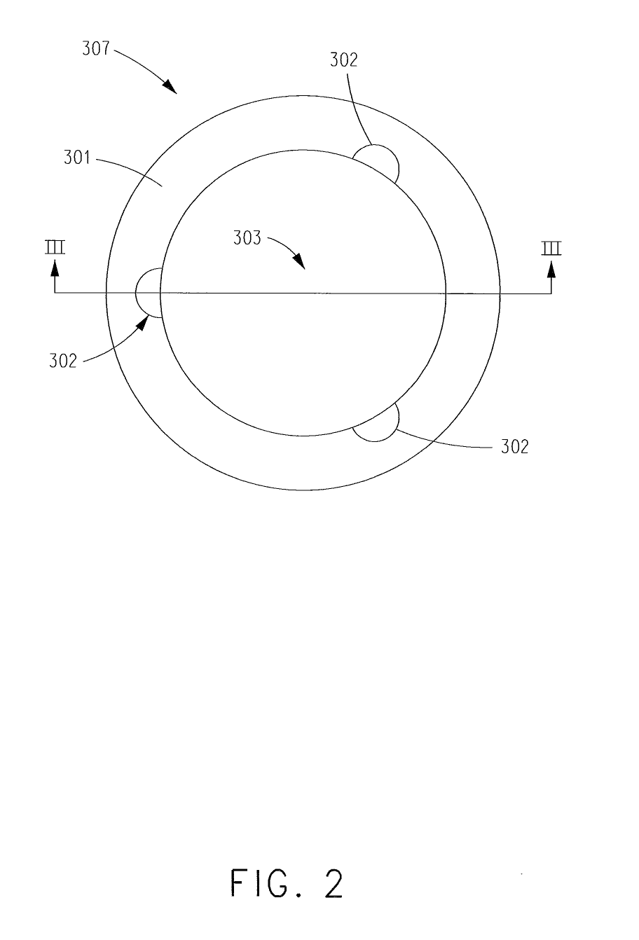

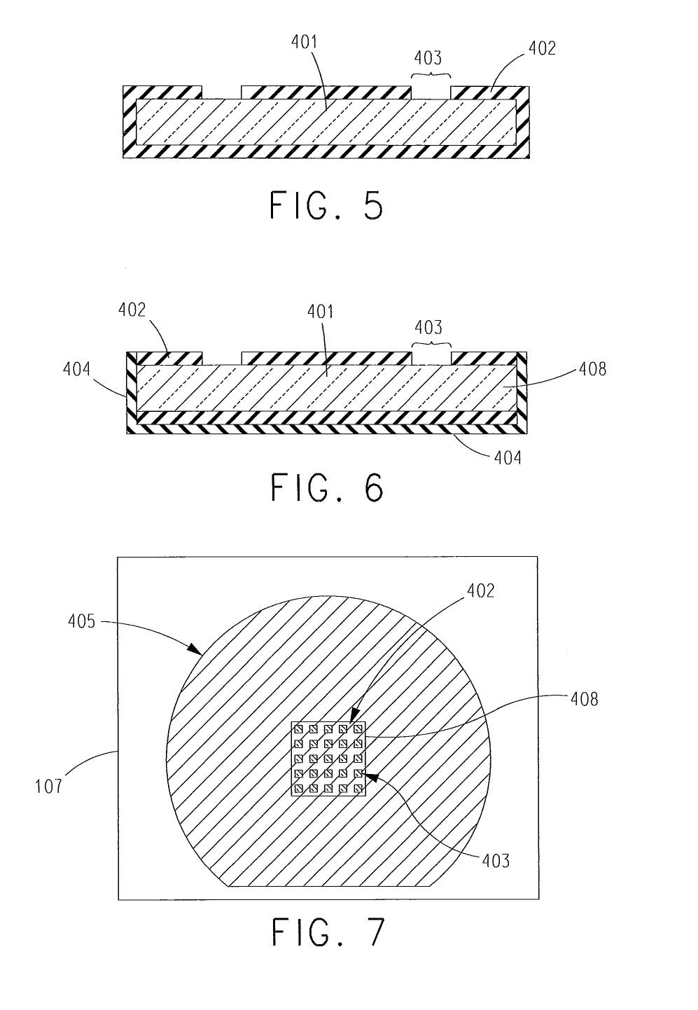

Three setups were used to quantify selectivity. Setup A is shown in FIGS. 2-4. Setup B is shown in FIGS. 5-8. Setup C is shown in FIGS. 9-13.

Setup A:

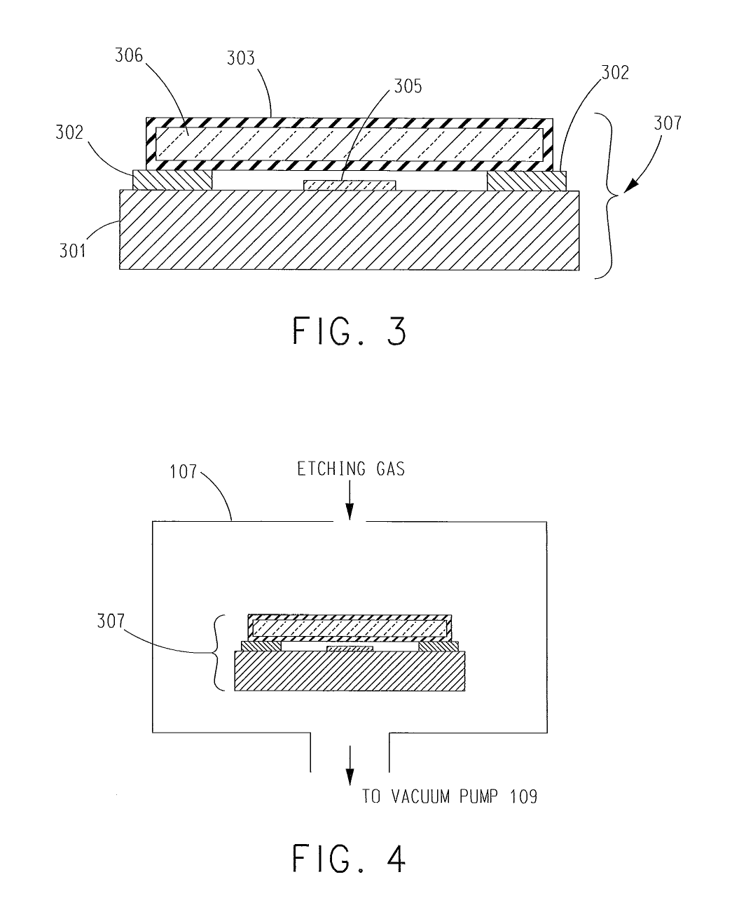

For setup A (FIGS. 2-4), FIG. 2 shows a plan view of a test assembly 307 and FIG. 3 shows a cross-sectional view of test assembly 307 taken along line in FIG. 2. A silicon wafer 306, e.g., a 100 mm diameter, 525 um thick silicon wafer, is coated with a 1.5 um thick layer of silicon nitride 303 (deposited using LPCVD at 835 C with a process pressure of 140 mTorr with a dichlorosilane flow of 100 sccm and an NH3 flow of 25 sccm). The layer of silicon nitride 303 is shown covering the entire wafer 306. Wafer 306 is suspended above an aluminum base 301 using aluminum standoffs 302 approximately 3 mm in height. Under silicon wafer 306 is a piece of silicon 305. The piece of silicon 305 is approximately square and is 10 mm on each side and is approximately 525 um thick. Other test materials other than silicon nitride 303 can be tested using this method.

The material of interest, in this case silicon nitride 303, should desirably coat the entire wafer 306 so that only the material of interest is exposed on the wafer 306. Alternatively, if the material of interest can only be deposited on one side of the wafer, then the back side of wafer 306 could be coated with a material having a slow etch rate, such as silicon dioxide, aluminum, or various polymers. Alternatively, wafer 306 can be replaced with a material having a slow etch rate, such as quartz or glass.

With reference to FIG. 4 and with continuing reference to FIGS. 2 and 3, test assembly 307 is located inside of etching chamber 107 (FIG. 1) for etching. Etching gas (with or without mixing gas(es)) is introduced into etching chamber 107 so that etching can occur. The etching gas is pumped out of etching chamber 107 via vacuum pump 109.

The piece of silicon 305 is carefully weighed both before and after the etch so that the pre and post etch weights can be used to determine the quantity of silicon that was etched. This is referred to as Δ mass silicon and is measured in mg. The thickness of the silicon nitride 303 is carefully measured before and after etching in the region directly opposite and facing the silicon piece 305 and is referred to as Δ silicon nitride thickness and is measured in μm. The selectivity ratio used with setup A is written as:

$$Selectivity Ratio = \frac{Δ mass silicon}{Δ silicon nitride thickness}$$

Note that the measurement as Δsilicon nitride thickness would be replaced by other material changes in thickness in cases where the material is not silicon nitride 303. In addition, Amass silicon would be replaced by other material mass change where silicon piece 305 is replaced with another material.

Setup B

For setup B (FIGS. 5-8), a 1 um thick silicon dioxide layer 402 is thermally grown on the entire surface of a 150 mm diameter, 600 um thick silicon wafer 401, as shown in FIG. 5. The silicon dioxide layer 402 on one side of wafer 401 is patterned with an array of openings 403 exposing the silicon substrate underneath. The openings 403 are 500 um square, and arranged in a grid with pitch 2500 um (shown best in FIG. 7). For clarity FIGS. 5 and 6 been simplified to show only two openings.

As shown in FIG. 6, the wafer is cleaved into approximately 25 mm square samples or pieces 408, and the back and edges of each sample 408 are coated with a thin (about 1 um) film of octafluorocyclobutane (RC318) 404 to avoid exposure of silicon on the cleaved edges. The sample 408 is placed on an aluminum carrier 405, as shown in the plan view of FIG. 7, and placed in vacuum chamber 107 for etching. Etching gas (with or without mixing gas(es)) is introduced into etching chamber 107 so that etching can occur. The etching gas is pumped out of etching chamber 107 via vacuum pump 109.

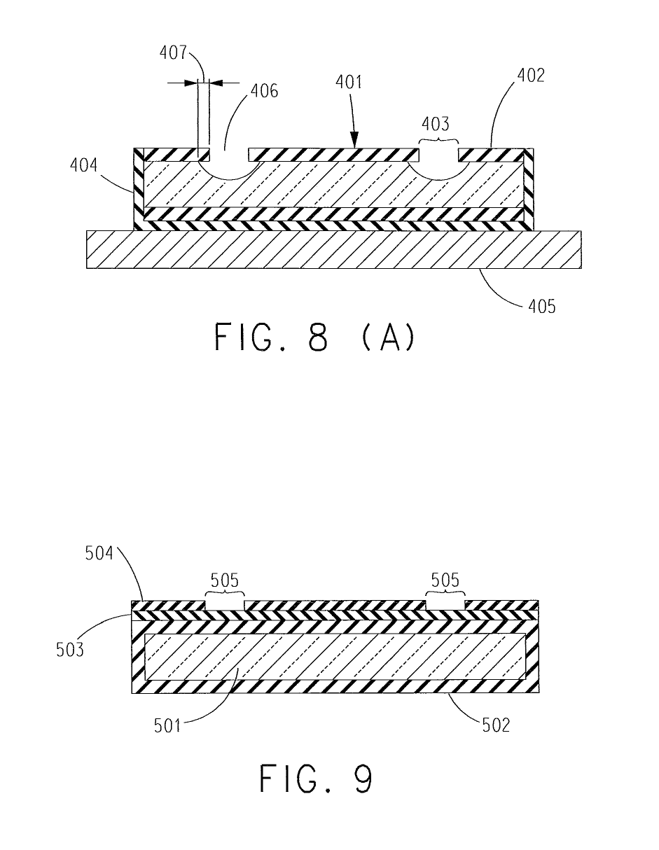

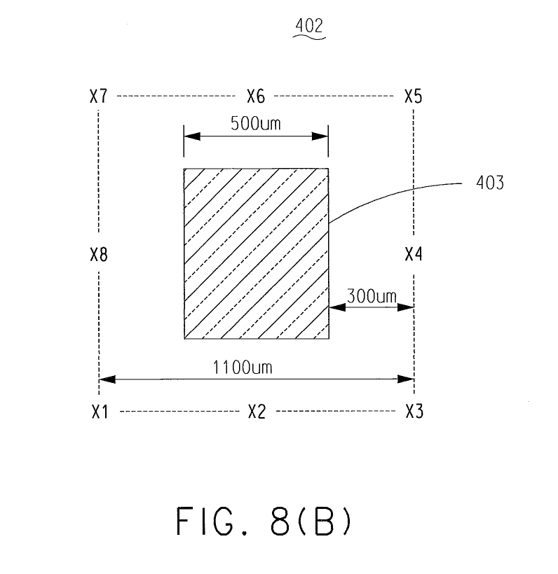

Etching sample 408 results in semispherical pits 406 in the silicon, shown in cross-sectional view of FIG. 8(A), which extend past the bottom edges of the patterned silicon dioxide by a distance or dimension called the “undercut” 407. The thickness of the silicon dioxide 402 is measured both before and after the etch so that the pre and post etch thicknesses can be used to determine the quantity of silicon dioxide that was etched. Desirably, measurement of the thickness of silicon dioxide 402 is taken at 8 points, labeled X1 to X8 in FIG. 8(B), and the median value is used as the measured thickness of silicon dioxide 402 before and after the etch. This is referred to as Δsilicon dioxide thickness and is measured in Angstroms. The undercut 407 is also measured in Angstroms. The selectivity ratio used is written as:

$$Selectivity Ratio = \frac{Undercut}{Δ silicon dioxide thickness}$$

Note that the measurement as Δ silicon dioxide thickness would be replaced by other material changes in thickness in cases where the material is not silicon dioxide 402. In addition, measurements of Si etch other than undercut could be used, for example, etch depth. The Si wafer could also be replaced with other materials, such as, without limitation, Si—Ge, or Ge, to name two examples.

### Setup C

Setup C (FIGS. 9-13) is intended to measure the relative selectivity of the etch of a buried low-pressure chemical vapor deposited (LPCVD) silicon nitride layer and the silicon on top of it. As shown in FIG. 9, a silicon wafer 501 (150 mm in diameter and 600 um thick) is enveloped with LPCVD silicon nitride 502 with a refractive index 2.03 and a thickness of 1000 Angstroms. An 8500 Angstroms thick layer of amorphous polysilicon 503 is deposited atop of the silicon nitride 502 on the top surface of wafer 501. The top of wafer 501 is then coated with photoresist 504 which is patterned with slits and holes 505 in various widths and densities. Only two openings 505 are shown for simplicity.

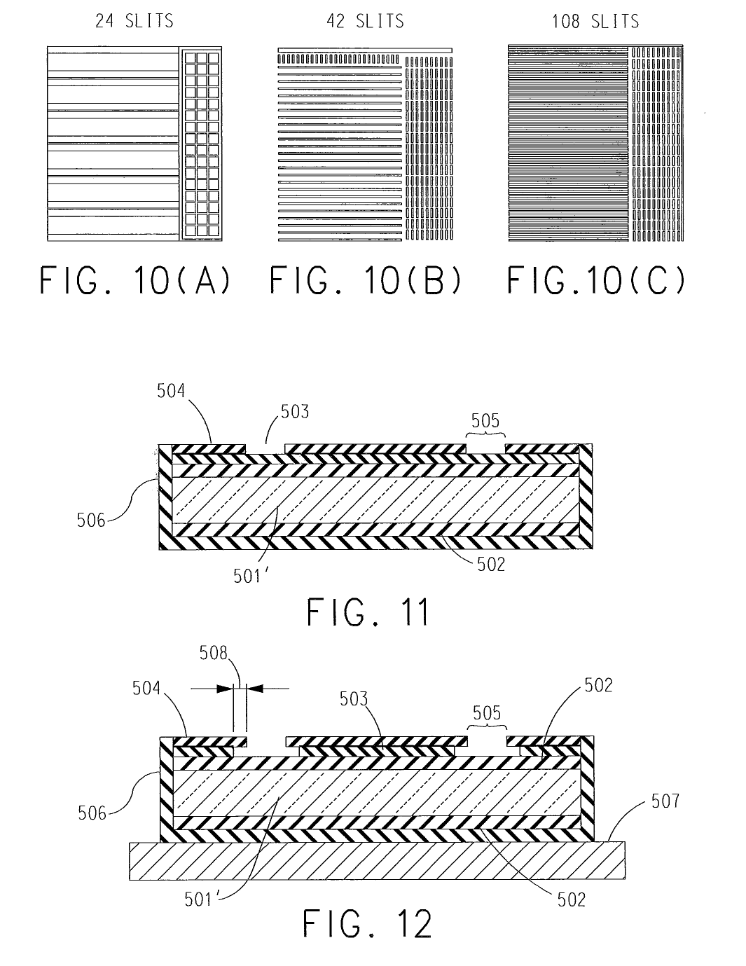

Depending on the density of the mask pattern, there are either 24, 42, or 108 slits per 10 mm square reticule. The slits are in groups containing widths of 2, 5, 10, 20, 50, and 100 um. The three mask patterns are shown in FIGS. 10(A)-10(C).

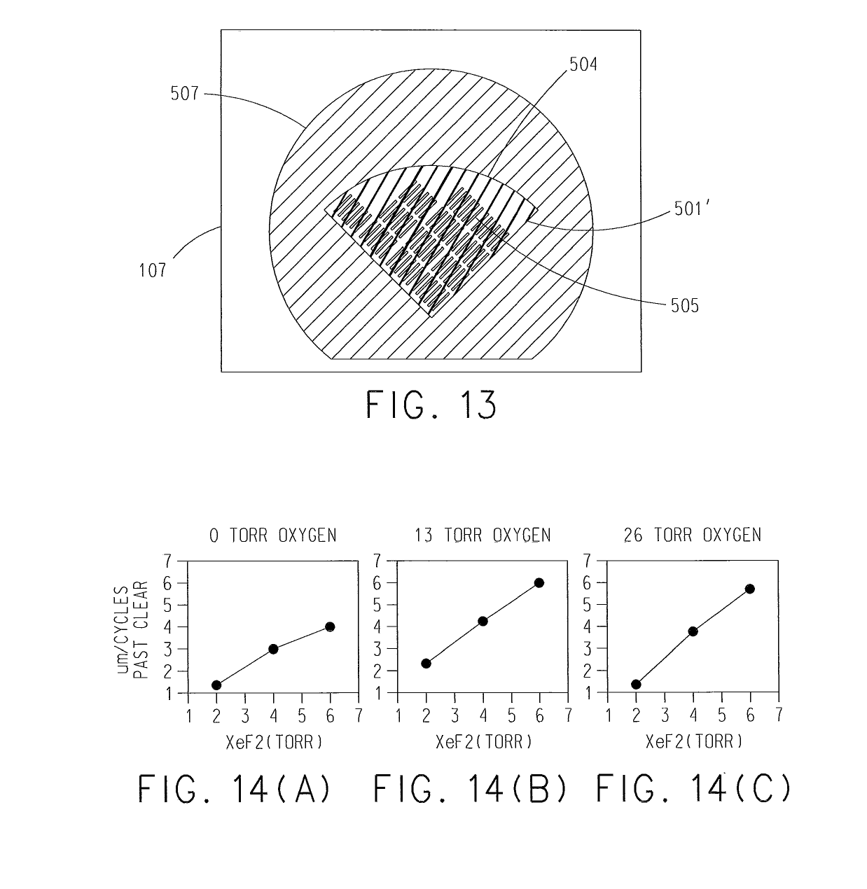

As shown in FIG. 11, wafer 501 is cleaved into 4 samples (quarters) 501′, and the back and sides of each quarter 501′ are coated with a thin (about 1 um) film of octafluorocyclobutane (RC318) 506 to avoid exposure of silicon on the cleaved edges. The wafer sample 501′ is placed on an aluminum carrier 507 as shown in cross-section view FIG. 12 and plan view in FIG. 13 and placed in vacuum chamber 107 for etching. Etching gas (with or without mixing gas(es)) is introduced into etching chamber 107 so that etching can occur. The etching gas is pumped out of etching chamber 107 via vacuum pump 109.

Etching wafer sample 501′ results in amorphous polysilicon 503 being removed between the top silicon nitride layer 502 and photoresist layer 504, as shown in FIG. 12. The distance or dimension 508 of amorphous polysilicon 503 removed under photoresist 504 is called the “undercut”. The sample was etched until the open areas were cleared, and then a number of cycles afterward until there was 15 to 20 um of undercut.

After etching, the photoresist 504 is removed with adhesive tape, exposing the silicon nitride 502 where the amorphous polysilicon 503 was etched away. The thickness of the silicon nitride 502 is measured in the center of undercut 508 using a Filmetrics F40 reflectometer with a spot size of 5 um, and subtracted from a known initial thickness to obtain the thickness change, referred to as Δ silicon dioxide thickness which is measured in Angstroms. The undercut is also measured in Angstroms. The selectivity ratio used is written as:

$$Selectivity Ratio = \frac{Undercut}{Δ silicon nitride thickness}$$

Note that the measurement as Δ silicon nitride thickness would be replaced by other material changes in thickness in cases where the material is not silicon nitride 502. In addition, measurements of Si etch other than undercut could be used, for example, etch depth. The Si wafer 501 could also be replaced with other materials, such as, without limitation, Si—Ge, or Ge, to name two examples.

### Example

### Silicon Nitride Selectivity, Setup A, Flush Between Pulses

The effect of using a flush between pulses of pure xenon difluoride with setup A on silicon nitride selectivity is shown in Table 1 below. In this case, the volume of expansion chamber 103, approximately 0.6 L, was filled with 3 Torr of xenon difluoride and the volume of etching chamber 107 (where etching took place) was approximately 2 L. The etch time was 15 seconds and the etching was done for 20 cycles. After each etching cycle, expansion chamber 103 was pumped out through the etching chamber until expansion chamber 103 reached 0.8 Torr. The temperature of the test assembly 307 was approximately 13° C. When etching chamber 107 was flushed with a flush gas from source 130 or 131, etching chamber 103 was filled to approximately 30 Torr after each etching cycle. Whether or not a flush gas was used, each cycle had a flush time of 10 seconds, so that there was a delay of 10 seconds between etch cycles. As shown in Table 1, the use of an oxygen flush gas improved the Selectivity Ratio of a factor of approximately 3 times that of not using any flush gas and at least 4 times better than using He or N2. Note that multiple entries of flush gas in Table 1 indicates repeats of that etch condition.

Herein, where the following Tables include “None” in the column for Gas, no flush gas was used and etching chamber 107 was simply pumped down to a pressure of approximately 0.3 Torr in preparation for each etching cycle.

TABLE 1

| | Selectivity |
|---|---|
| Flush Gas | Ratio |
| None | 17 |
| None | 21 |
| He | 10 |
| O2 | 93 |
| O2 | 60 |
| He | 13 |
| N2 | 10 |

### Example

### Silicon Nitride Selectivity, Setup A, Diluted Xenon Difluoride Pulses

The effect of pulses of xenon difluoride mixed with a mixing gas from source 112, with setup A, on silicon nitride selectivity is shown in Table 2. In this case, the volume of expansion chamber 103, approximately 0.6 L, was filled with 3 Torr of xenon difluoride and an additional 10 Torr of mixing gas from source 112, and the volume of the etching chamber 107 (where etching took place) was approximately 2 L. The etch time was 15 seconds and etching was done for 20 cycles. After each etching cycle, expansion chamber 103 was pumped out through etching chamber 107 until expansion chamber 103 reached 1.2 Torr. The temperature of the test setup was approximately 13° C. After each etching cycle there was a delay of 10 seconds between etch cycles. As shown in Table 2, the use of oxygen as a mixing gas showed an improvement in the Selectivity Ratio of a factor of approximately 30 times better than using N2 and approximately 26 times better than no mixing gas.

TABLE 2

| | Selectivity |
|---|---|
| Mixing Gas | Ratio |
| None | 7 |
| N2 | 6 |
| O2 | 181 |

### Example

### Silicon Nitride Selectivity, Setup A, Diluted Continuous Flow

The effect of using a continuous flow of xenon difluoride mixed with other gases from source 130 or 131, with setup A, on silicon nitride selectivity is shown in Table 3. In this case, the volume of expansion chamber 103, approximately 0.6 L, was filled with xenon difluoride and the volume of etching chamber 107 was approximately 2 L. The etch time was 8 minutes and a continuous flow of 6 sccm of xenon difluoride and a dilution gas from source 130 or 131 was supplied to etching chamber 107. The pressure inside of etching chamber 107 was controlled to 0.7 Torr. The temperature of the test assembly 307 was approximately 13° C. As shown in Table 3, the use of oxygen as the mixing gas showed an improvement in the Selectivity Ratio of a factor of at least 12 times better than not using a mixing gas, and at least 3 times better than using either argon or nitrogen as the mixing gas. Note that multiple entries of an etch condition indicate repeats of that etch condition.

TABLE 3

| Dilution Gas | Dilution gas flow (sccm) | Selectivity Ratio |
|---|---|---|
| None | | 7 |
| O2 | 10 | 125 |
| O2 | 10 | 89 |
| Ar | 14 | 27 |
| N2 | 10 | 12 |

### Example

### Silicon Dioxide Selectivity, Setup A, Flush Between Pulses

The effect of using a flush between pulses of pure xenon difluoride, with setup A, on silicon dioxide is shown in Table 4. For this experiment, the silicon nitride coated silicon wafer used in the previous examples was replaced with a wafer having a coating of thermally grown silicon dioxide. In this example, the volume of expansion chamber 103, approximately 0.6 L, was filled with 3 Torr of xenon difluoride and the volume of etching chamber 107 was approximately 2 L. The etch time was 15 seconds and etching was done for 20 cycles. After each etching cycle, expansion chamber 103 was pumped out through etching chamber 107 until expansion chamber 103 reached 0.8 Torr. The temperature of the test assembly 307 was approximately 13° C. When a flush gas from source 130 or 131 was used, etching chamber 103 was filled with xenon difluoride to approximately 30 Torr after each etching cycle. Whether or not flush gas was used, the flush time was 10 seconds, so that there was a delay of 10 seconds between etch cycles. As shown in Table 4, the use of an oxygen flush gas showed an improvement in the Selectivity Ratio of a factor of approximately 5.6 times that of not using any flush gas and approximately 2.6 times that of using nitrogen flush gas.

TABLE 4

| | Selectivity |
|---|---|
| Flush Gas | Ratio |
| O2 | 9200 |
| None | 1620 |
| He | 896 |
| N2 | 3483 |

### Example

### Silicon Dioxide Selectivity, Setup B, Diluted Pulsed Flow

The effect of pulses of xenon difluoride mixed with a mixing gas from source 112, using setup B, on silicon dioxide is shown in Table 5. In this case, the volume of expansion chamber 103, approximately 0.6 L, was filled with 4 Torr of xenon difluoride and 13 Torr of mixing gas, except where there was None, and the etching chamber volume was approximately 2 L. The etch time was 15 seconds and the etching was done for 15 cycles. After each etching cycle, expansion chamber 103 was pumped out through etching chamber 107 until expansion chamber 103 reached 5 Torr. The temperature of this test setup (discussed above in connection with FIGS. 5-8) was approximately 13° C. There was a delay of 10 seconds between etch cycles. In this example, the selectivity is defined as the ratio of undercut 407 in the silicon divided by the change in thickness of the silicon dioxide. A value of “infinite” indicates that the change in silicon dioxide thickness was too small to be measured.

As shown in Table 5, the use of oxygen showed an improvement in the Selectivity Ratio of a factor of at least 23 times that of not using any dilution gas and approximately 21 times that of using the next best gas, i.e., helium gas. Note that multiple entries of an etch condition indicate repeats of that etch condition.

TABLE 5

| | Selectivity |
|---|---|
| Mixing Gas | Ratio |
| O2 | Infinite |
| O2 | 94000 |
| O2 | 125000 |
| He | 4095 |
| He | 4444 |
| N2 | 3478 |
| N2 | 4111 |
| None | 3529 |
| None | 3617 |
| None | 3797 |
| None | 4000 |

### Example

### Silicon Dioxide Selectivity, Setup B, Diluted Continuous Flow

The effect of a continuous flow of xenon difluoride diluted with a mixing gas from source 112, using setup B, on silicon dioxide selectivity, is shown in Table 6. The dilution gas from source 112 was mixed with 10 sccm of pure xenon difluoride in expansion chamber 103 before entering etching chamber 107. The etch time was 6 minutes and the process pressure was controlled at 2 Torr. Note that multiple entries of an etch condition in Table 6 indicate repeats of that etch condition. As shown in Table 6, the addition of oxygen caused an improvement in selectivity by a factor of at least 1.19 over the next best case, helium, and a factor of at least 1.73 over no dilution gas. The flow rate for each dilution gas used in this example is shown in Table 6.

TABLE 6

| | Dilution | |
|---|---|---|
| | gas flow | Selectivity |
| Dilution gas | (sccm) | ratio |
| O2 | 6.8 | 5341 |
| O2 | 6.8 | 6250 |
| He | 10 | 4483 |
| Ar | 9.6 | 4353 |
| Ar | 9.6 | 4419 |
| N2 | 6.9 | 4037 |
| N2 | 6.9 | 4167 |
| None | 0 | 2624 |
| None | 0 | 2973 |
| None | 0 | 3088 |

### Example

### Silicon Nitride Selectivity, Setup C, Diluted Pulsed Mode

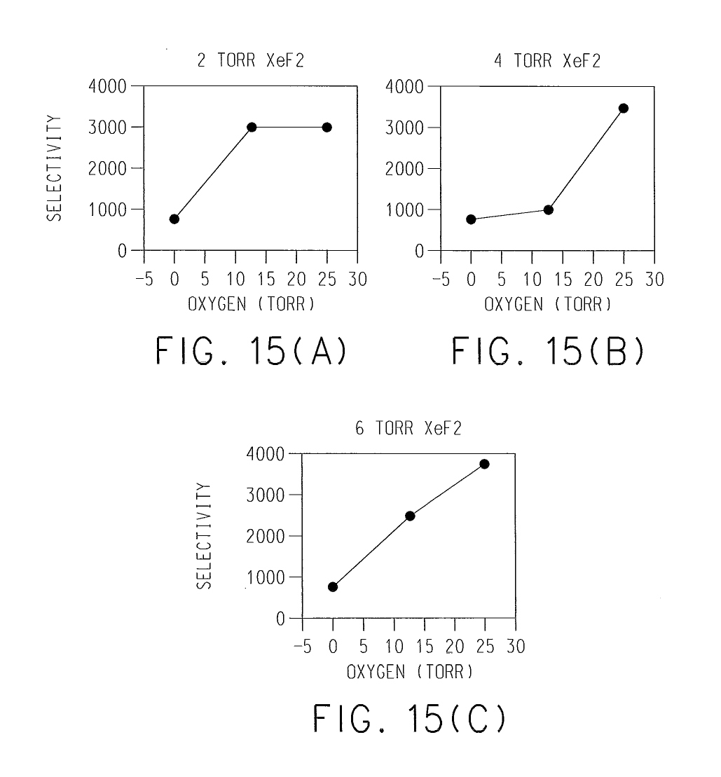

The effects of a pulsed flow of xenon difluoride diluted with mixing gas from source 112 in expansion chamber 103, using setup C, on silicon nitride selectivity, is shown in FIGS. 14(A)-15(C). In this example, wafer quarters with 108 slits per 10 mm reticule were used. The slit pattern is designed to have about 34% open area (exposed silicon). Three different pressures of xenon difluoride were used (2, 4, and 6 Torr) in etching chamber 107 in combination with three different pressures of oxygen (0, 13, and 26 Torr) in etching chamber 107. Each sample was run until the open areas were observed to be cleared down to the top silicon nitride layer 502, then a number of cycles were run until the undercut was in the range of 15-20 um. Etch rate was defined as the distance or dimension of undercut divided by the number of cycles after the open areas cleared. The cycle times were in the range from 27 to 31 seconds, depending on total pressure. The results for etch rate are shown in FIGS. 14(A)-14(C), and the results for the selectivity are shown in FIGS. 15(A)-15(C). As shown in FIGS. 14(A)-14(C), the etch rate depends mainly on the partial pressure of xenon difluoride. As shown in FIGS. 15(A)-15(C), selectivity depends mainly on the partial pressure of oxygen. Hence, selectivity improvements are not caused by the etching being slower. As shown in FIG. 15(C), the selectivity at 6 Torr of xenon difluoride pressure improved from about 662 to 3778 (a factor of 5.7) with an increase in the partial pressure of oxygen from 0 Torr to 25 Torr.

The following Table 7 is a summary of selectivity ratio improvement for using oxygen vs. pure xenon difluoride. Values show worst cases measured. The value for setup C is for 6 Torr of xenon difluoride and 26 Torr of oxygen case.

TABLE 7

| O2 Vs. Pure | Setup and Material | | | |
|---|---|---|---|---|
| Xef2 | A—Silicon | A—Silicon | B—Silicon | C—Silicon |
| PROCESS | Nitride | Dioxide | Dioxide | Nitride |
| Flush Between | 2.9 | 5.7 | | |
| Cycles | | | | |
| Diluted pulses | 25.9 | | 23.5 | 5.7 |
| Diluted | 12.7 | | 1.7 | |
| continuous | | | | |

The following Table 8 is a summary of selectivity ratio improvement for using oxygen vs. nitrogen. Values show worst cases measured.

TABLE 8

| | Setup and Material | | |
|---|---|---|---|
| O2 Vs. N2 | A—Silicon | A—Silicon | B—Silicon |
| PROCESS | Nitride | Dioxide | Dioxide |
| Flush Between | 6.0 | 2.6 | |
| Cycles | | | |
| Diluted pulses | 30.2 | | 22.9 |
| Diluted | 7.4 | | 1.3 |
| continuous | | | |

The present invention has been described with reference to desirable embodiments. Obvious modifications and alterations will occur to others upon reading and understanding the preceding detailed description. For example, it is believed that adding oxygen to the etching process may also improve the selectivity of downstream NF3+Xe plasma processes as well. It is intended that the present invention be construed as including all such modifications and alterations insofar as they come within the scope of the appended claims or the equivalents thereof.

The invention claimed is:

1. A vapor etching method comprising:
(a) placing a material to be etched and an etch resistant material into an etching chamber;
(b) following step (a), adjusting a pressure in the etching chamber to a desired pressure; and
(c) following step (b), exposing the materials in the etching chamber to an etching gas and to an amount of a gas that comprises oxygen that is selected to obtain a desired selectively ratio of a change in the material to be etched caused by said exposure over a change in the etch resistant material caused by said exposure.

2. The method of claim 1, wherein:
the change in the material to be etched caused by said exposure is either (1) a change in a mass of the material to be etched caused by said exposure or (2) a change in a dimension of the material to be etched caused by said exposure; and
the change in the etch resistant material caused by said exposure is a change in a dimension of the etch resistant material caused by said exposure.

3. The method of claim 1, wherein the selectively ratio is no less than 60.

4. The method of claim 1, wherein the selectively ratio is between 60 and 125000.

5. The method of claim 1, wherein step (c) includes exposing the substrate to either a continuous flow of the etching gas diluted with the gas that comprises oxygen or to plural pulses of etching gas diluted with the gas that comprises oxygen.

6. The method of claim 5, wherein the dilution of the etching gas with the gas that comprises oxygen occurs either prior to or concurrent with said exposure.

7. The method of claim 1, wherein step (c) includes sequentially exposing the materials to (1) the etching gas and (2) to the gas that comprises oxygen.

8. The method of claim 1, wherein step (c) includes sequentially exposing the materials to (1) the etching gas absent the gas that comprises oxygen and (2) to the gas that comprises oxygen absent the etching gas.

9. The method of claim 7, wherein step (c) includes sequentially exposing the substrate to the etching gas and the gas that comprises oxygen for a number of cycles.

10. The method of claim 1, wherein:
the etching gas is xenon difluoride; and
the gas that comprises oxygen is O₂.

11. The method of claim 1, wherein the material to be etched is comprised of one or more of the following: silicon, germanium, tungsten, titanium, zirconium, hafnium, vanadium, tantalum, niobium, boron, phosphorous, arsenic, and molybdenum.

12. The method of claim 1, wherein the etch resistant material is comprised of one or more of the following: silicon dioxide, silicon nitride, silicon carbon nitride, silicon oxynitride, nickel, aluminum, photoresist, phosphosilicate glass, boron phosphosilicate glass, polyimides, gold, copper, platinum, chromium, aluminum oxide, silicon carbide, titanium, tantalum, tantalum-nitride, titanium-nitride, tungsten, and titanium-tungsten.

13. A vapor etching system comprising:
an etching chamber;
a vacuum pump;
a plurality of valves; and
a controller operative for controlling the opening and the closing of the valves to:
cause the vacuum pump to reduce pressure in the etching chamber to below atmospheric pressure when an etch resistant material and a material to be etched are positioned in the etching chamber;
cause an etching gas to be supplied to the pressure reduced etching chamber; and
cause an amount of gas comprising oxygen to be supplied to the pressure reduced etching chamber, either concurrent with the supply of etching gas or separate from the supply of etching gas, that produces a desired ratio of etching of the material to be etched versus etching of the etch resistant material.

14. The system of claim 13, further including an expansion chamber, wherein the controller is operative for controlling the plurality of valves to charge the expansion chamber with either the etching gas alone or a combination of the etching gas and the gas comprising oxygen, and for causing the gas in the expansion chamber to be supplied to the pressure reduced etching chamber from the expansion chamber.

15. The system of claim 14, wherein the controller is operative for causing the gas comprising oxygen to be supplied to the pressure reduced etching chamber concurrent with the supply of etching gas to the pressure reduced etching chamber from the expansion chamber.

16. The system of claim 13, wherein the controller is operative for:
causing plural pulses of the etching gas to be supplied to the pressure reduced etching chamber; and
causing the gas comprising oxygen to be supplied to the pressure reduced etching chamber between at least one pair of temporally adjacent pulses of the etching gas.

17. A vapor etching method comprising:
(a) providing a substrate comprised of a material to be etched and at least one etch resistant material;
(b) exposing said substrate to an etching gas in the presence of a pressure below atmospheric pressure; and
(c) exposing said substrate to an amount of gas comprising oxygen, in the presence of a pressure below atmospheric pressure, that produces a desired ratio of etching of the material to be etched versus etching of the etch resistant material, wherein the substrate is exposed to the gas comprising oxygen either concurrent with the exposure of said substrate to the etching gas in step (b) or separately from the exposure of said substrate to the etching gas in step (b).

18. The method of claim 17, further including repeating steps (b) and (c) until the etch resistant material has been etched to at least a predetermined extent.

19. The method of claim 17, wherein exposing the substrate to the gas comprising oxygen concurrent with the exposure of said substrate to the etching gas includes either:
diluting the etching gas with the gas comprising oxygen prior to said exposure; or
combining separate flows of the gas comprising oxygen and the etching gas just prior to said exposure.

20. The method of claim 17, wherein exposing the substrate to the gas comprising oxygen separately from the exposure of said substrate to the etching gas includes:
exposing said substrate to a number of separate instances of the etching gas; and
between at least two instances of exposing said substrate to the etching gas, exposing said substrate to an instance of the gas comprising oxygen.

21. The method of claim 17, wherein:
the material to be etched is comprised of one or more of the following: silicon, germanium, tungsten, titanium, zirconium, hafnium, vanadium, tantalum, niobium, boron, phosphorous, arsenic, and molybdenum; and
the etch resistant material is comprised of one or more of the following: silicon dioxide, silicon nitride, silicon carbon nitride, silicon oxynitride, nickel, aluminum, photoresist, phosphosilicate glass, boron phosphosilicate glass, polyimides, gold, copper, platinum, chromium, aluminum oxide, silicon carbide, titanium, tantalum, tantalum-nitride, titanium-nitride, tungsten, and titanium-tungsten.
